(19) United States
(12) Patent Application Publication
(10) Pub. No.: US 2026/0096497 A1
(43) Pub. Date: Apr. 2, 2026

(54) BALL GRID ARRAY (BGA) STRUCTURE FOR DROP-SHOCK PERFORMANCE

(71) Applicant: Qorvo US, Inc., Greensboro, NC (US)

(72) Inventor: MD Hasnine, Richardson, TX (US)

(21) Appl. No.: 19/263,575

(22) Filed: Jul. 9, 2025

Related U.S. Application Data
(60) Provisional application No. 63/700,293, filed on Sep. 27, 2024.

(51) Int. Cl. H01L 23/498; H01L 21/48; H01L 23/00; H01L 23/31; H01L 23/34

(52) U.S. Cl. CPC H10W 90/701; H10W 70/093; H10W 70/66; H10W 90/401; H10W 40/00; H10W 74/117; H10W 90/724

(57) ABSTRACT

Ball grid array (BGA) structures for drop-shock performance are disclosed. In one aspect, balls within the BGA may have a copper core plated with a highly ductile solder. In exemplary aspects, the copper is coated with an indium solder. A nickel barrier may optionally be positioned between the copper and the indium to prevent the formation of intermetallic compounds (IMCs) between the copper and indium. The high ductility of the copper allows plastic deformation during drop-shock events, while the indium provides the desired soldering function.

### PRIORITY APPLICATION

The present application claims priority to U.S. Provisional Patent Application Ser. No. 63/700,293 filed on Sep. 27, 2024, and entitled “BALL GRID ARRAY (BGA) STRUCTURE FOR DROP-SHOCK PERFORMANCE,” the disclosure of which is incorporated herein by reference in its entirety.

### BACKGROUND

### I. Field of the Disclosure

The technology of the disclosure relates generally to electronic components and, more particularly, to a ball grid array (BGA) on such components that can withstand drop-shock events.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. Not surprisingly, with the increased number of devices, the number of accidents, such as dropping, has increased. Concurrently, the size constraints of mobile devices have caused some creative solutions for spreading heat generated within the mobile devices. The use of heat-spreading elements within integrated circuit packages has added weight to the devices and introduces complex strains during dropping events. Finding a balance between appropriate heat spreading and structural strength to withstand drops provides room for innovation.

### SUMMARY

Aspects disclosed in the detailed description include ball grid array (BGA) structures for drop-shock performance. In particular, balls within the BGA may have a copper core plated with a highly ductile solder. In exemplary aspects, the copper is coated with an indium solder. A nickel barrier may optionally be positioned between the copper and the indium to prevent the formation of intermetallic compounds (IMCs) between the copper and indium. The high ductility of the copper allows plastic deformation during drop-shock events, while the indium provides the desired soldering function.

In this regard, in one aspect, a package is disclosed. The package includes a substrate, a chip positioned on the substrate, a first plurality of uniform balls forming a ball grid array (BGA) and configured to provide electrical connections to the chip, and a second plurality of non-uniform balls positioned proximate an outer periphery of the substrate.

In another aspect, an assembly is disclosed. The assembly includes a printed circuit board (PCB) and a package bonded to the PCB through a ball grid array (BGA). The package includes a substrate, a chip positioned on the substrate, the BGA positioned on a bottom surface of the substrate. The BGA comprises a first plurality of uniform balls configured to provide electrical connections to the chip and bond the package to the PCB, and a second plurality of non-uniform balls positioned proximate an outer periphery of the substrate.

In another aspect, a method of attaching a package to a printed circuit board (PCB) is disclosed. The method includes providing a first plurality of uniform balls in a ball grid array (BGA) of the package, providing a second plurality of non-uniform balls in the BGA at an outer edge of the package, and reflowing the uniform and non-uniform balls to attach the package to the PCB.

### BRIEF DESCRIPTION OF THE DRAWINGS

FIG. 1 is a cross-sectional view of a conventional electronic circuit package mounted on a printed circuit board (PCB) using a ball grid array (BGA);

FIG. 2A is a side elevational view of two packages from FIG. 1 on a PCB before a drop-shock event;

FIG. 2B is a side elevational view of the two packages of FIG. 2A during a drop-shock event where the PCB has deflected, causing strain on the BGA;

FIG. 3 is a ball with a copper core in a solder sheath according to aspects of the present disclosure;

FIG. 4A is a side elevational view of a ball of FIG. 3 positioned on a PCB before solder reflow;

FIG. 4B is a side elevational view of the ball of FIG. 4A after solder reflow;

FIG. 5 is a plan view of a bottom side of a package with a BGA formed from the balls of FIG. 3;

FIG. 6 is a cross-sectional view of the package of FIG. 5;

FIG. 7 is a plan view of a bottom side of a package with an alternate BGA, according to aspects of the present disclosure;

FIG. 8A is a plan view of a bottom side of a package with another alternate BGA having a ring lead frame, according to aspects of the present disclosure;

FIG. 8B is a plan view of a bottom side of a package with another alternate BGA, according to aspects of the present disclosure;

FIG. 9 is a flowchart illustrating an exemplary process for forming a package with a BGA formed from balls of the present disclosure;

FIGS. 10A-10H illustrate side views of package formation according to the process of FIG. 9; and

FIG. 11 is a block diagram of a wireless communication device, which may include packages with BGAs formed from balls, according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims, it is herein defined to be within five percent (5%).

Aspects disclosed in the detailed description include ball grid array (BGA) structures for heat spreading. In particular, balls within the BGA may have a copper core plated with a highly ductile solder. In exemplary aspects, the copper is coated with an indium solder. A nickel barrier may optionally be positioned between the copper and the indium to prevent formation of intermetallic compounds (IMCs) between the copper and indium. The high ductility of the copper allows plastic deformation during drop-shock events, while the indium provides the desired soldering function.

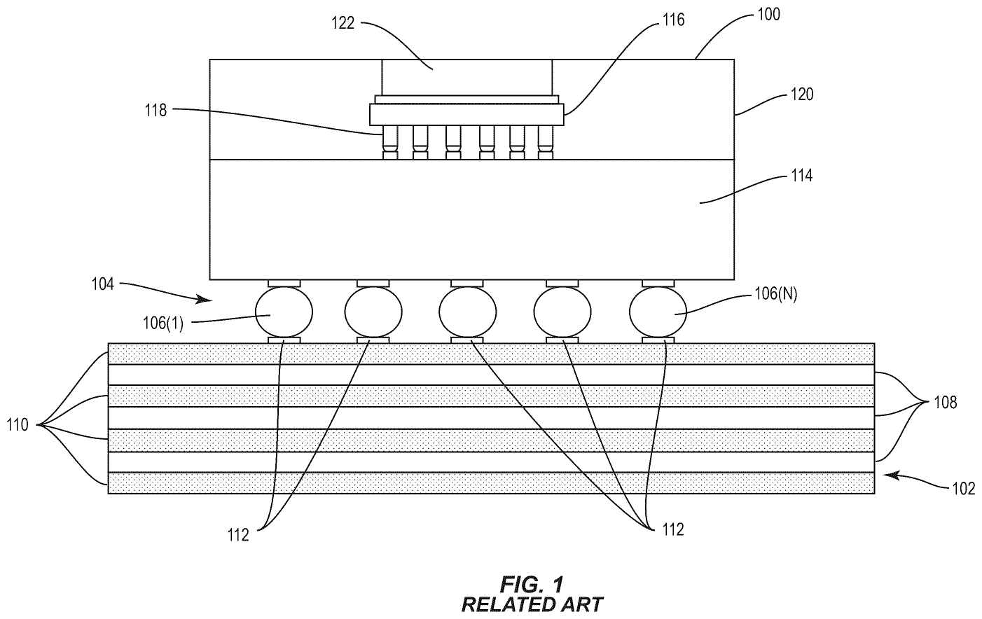

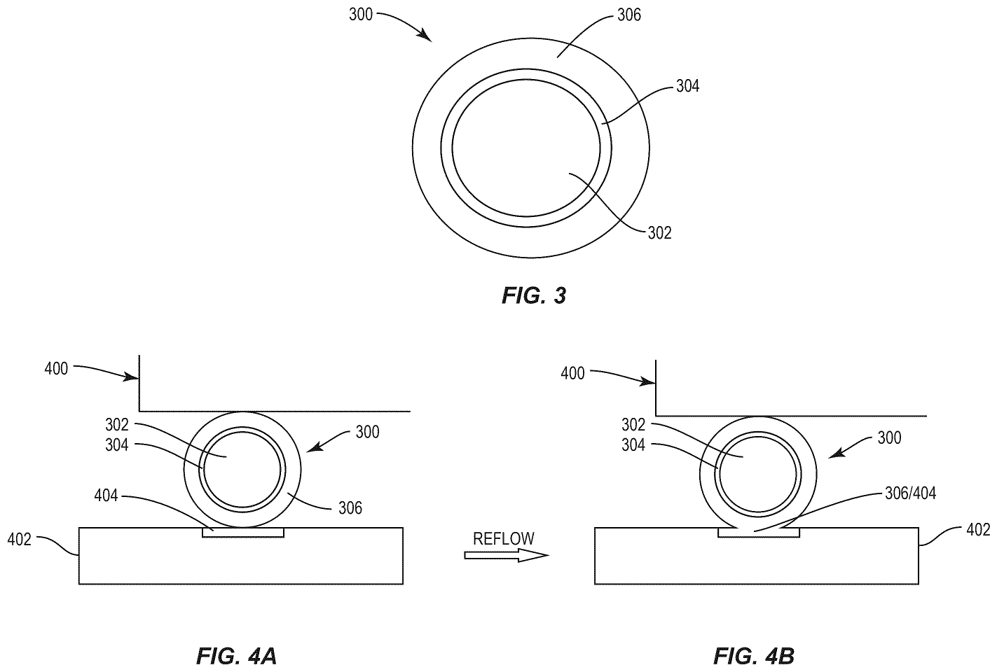

Before addressing aspects of the present disclosure, a brief overview of a conventional electronic package with conventional balls for the BGA is provided, beginning with reference to FIG. 1. A discussion of aspects of the present disclosure begins below with reference to FIG. 3.

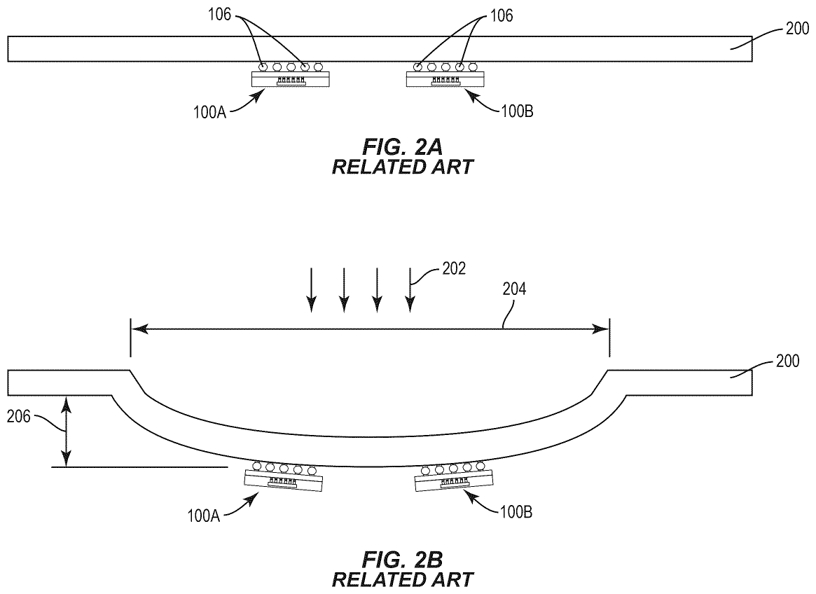

In this regard, FIG. 1 is a cross-sectional view of a package 100 coupled to a PCB 102 through a BGA 104 formed from balls 106(1)-106(N). As is well known, the PCB 102 may have interior metal layers 108 interleaved with dielectric material layers 110. The balls 106(1)-106(N) are generally formed from a solder material that will bond with solder paste 112 on a top surface of the PCB 102 during a reflow process. The package 100 may include a substrate 114 and a chip 116 positioned thereon coupled to metallization layers (not shown) in the substrate 114 through pins or copper pillars with solder caps 118. Mold compound 120 may surround the chip 116. A heat spreader 122 may be coupled to a top side of the chip 116 through a sinter material or the like. The heat spreader 122 may be a silicon carbide material or the like and is designed to facilitate the removal of heat generated in the chip 116. Unfortunately, the heat spreader 122 adds mass to the package 100. The impact of this extra mass is illustrated in FIGS. 2A and 2B.

Specifically, FIG. 2A illustrates two packages 100A, 100B, on a PCB 200 during normal operation. The PCB 200 is planar and there is approximately equal load on all balls 106 of each package 100A, 100B. However, during a drop event (e.g., a user drops their mobile phone), the PCB 200 experiences a load 202 across a load span 204. The load 202 causes the PCB 200 to deflect by a displacement 206. The deflection is exacerbated by the increased mass of the heat spreader 122 (not shown in FIGS. 2A/2B). That is, the moment of inertia of the package 100 with the heat spreader 122 is greater than the moment of inertia of a similarly sized package that lacks a heat spreader. This displacement induces differential flexing between the packages 100A, 100B, and the PCB 200, leading to plastic deformation of the solder joints. Sufficient stress (either one-time or cumulative) may cause failure of the electric connection of the BGA 104, which may lead to failure to operate. Empirical evidence indicates that the highest stress is on the exterior balls.

Aspects of the present disclosure provide an improved ball structure, which helps absorb the differential flexing and prevent drop-induced failure through the high ductility of the ball. In this regard, the ball may be formed from a copper core surrounded by an indium solder sheath. The copper may be separated from the indium by a layer of nickel. This separation prevents the formation of intermetallic compounds (IMC) that might otherwise occur at the copper-indium interface.

In this regard, FIG. 3 provides a cross-sectional view of a ball 300 with a copper core 302, a nickel-plating layer 304, and an indium solder plating outer layer 306. During attachment of a flip-chip package 400 to a PCB 402, as illustrated in FIGS. 4A & 4B, the PCB 402 may have a flux material 404 that melts and intermixes with the indium solder plating outer layer 306 during reflow such that a strong bond is formed between PCB 402 and the ball 300. Note that the nickel-plating layer 304 may not melt during reflow such that the copper core 302 does not intermix with the indium or the flux material 404.

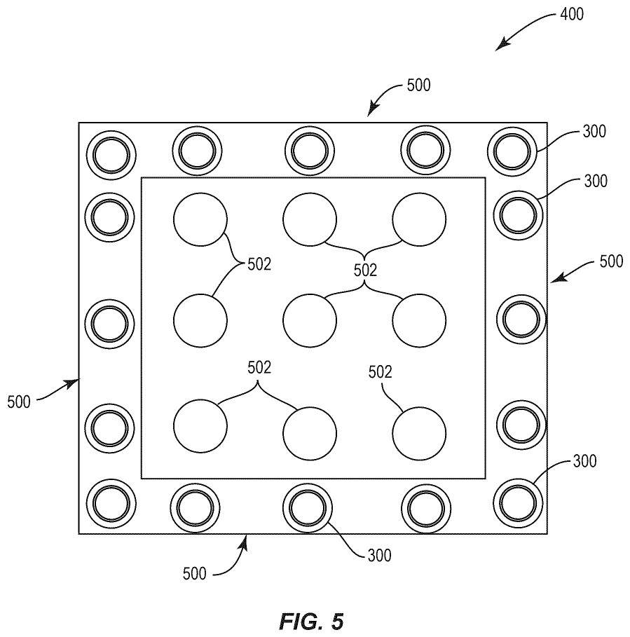

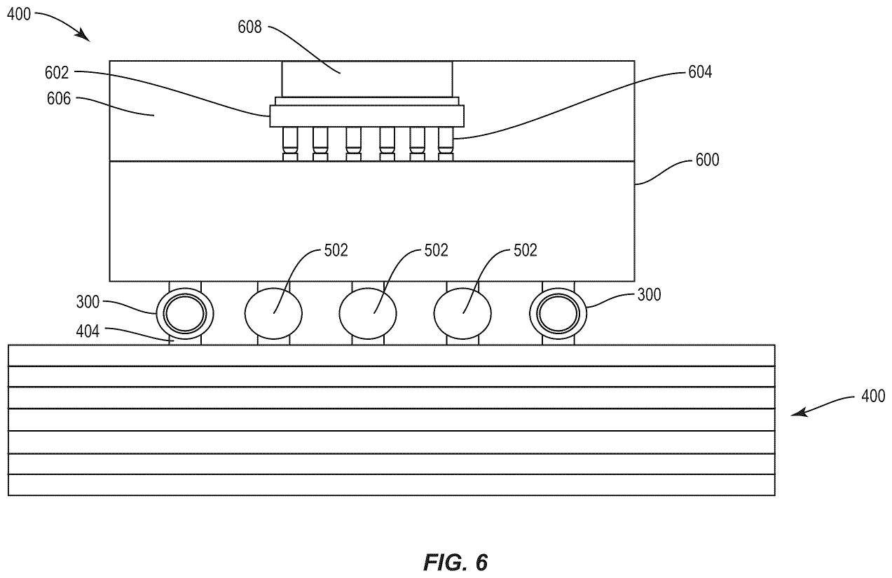

In practice, there are a variety of ways that the balls 300 may be placed on a package 400. Thus, as illustrated in FIGS. 5 & 6, the balls 300 may be positioned around a periphery of the package 400, proximate a circumferential edge 500. Solder balls 502 may be positioned interiorly of the balls 300 such that they are spaced from the circumferential edge 500. The solder balls 502 may lack the copper core 302 and may be all solder material (e.g., indium). As better illustrated in FIG. 6, the package 400 may be similar to package 100 and include a substrate 600 with a chip 602 positioned thereon coupled to metallization layers (not shown) in the substrate 600 through pins or copper pillars with solder caps 604. Mold compound 606 may surround the chip 602. A heat spreader 608 may be coupled to a top side of the chip 116 through a sinter material or the like.

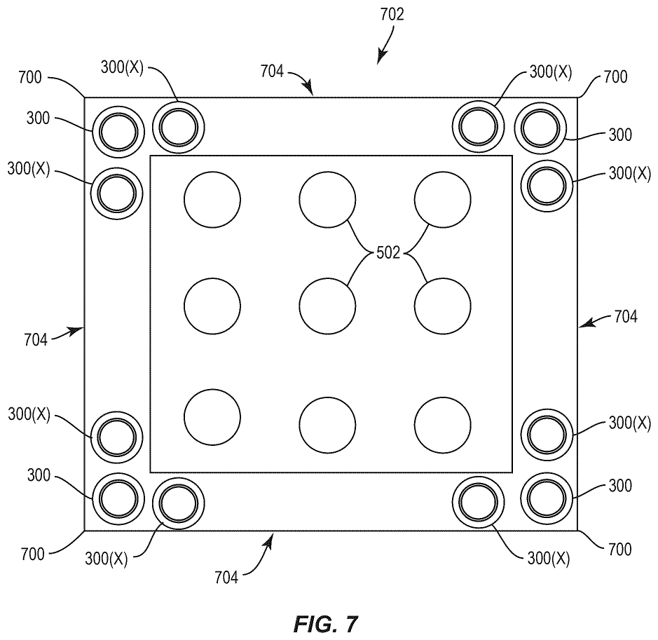

As shown in FIG. 7, and in contrast to FIG. 5 and the placement around all the periphery, it is also possible to just place the balls 300 at the corners 700 of a package 702 where balls 502 are still placed interiorly. As illustrated, the balls 300 are placed at the corner, and at least one ball on the sides 704 (e.g., ball 300(X)).

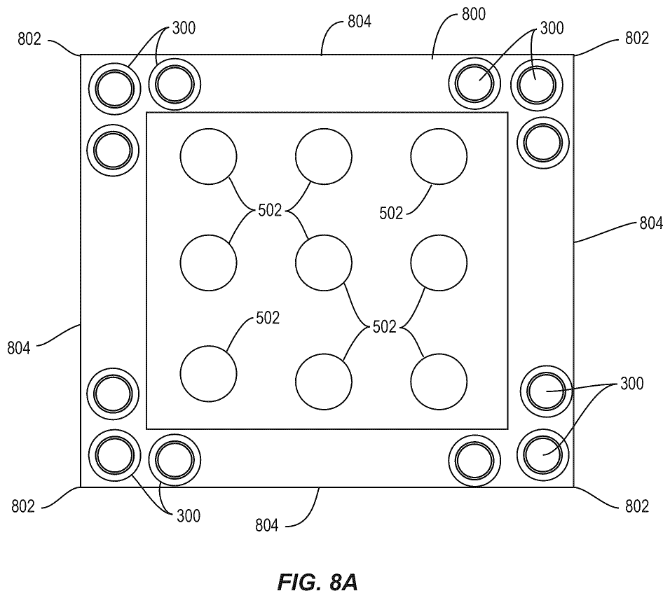

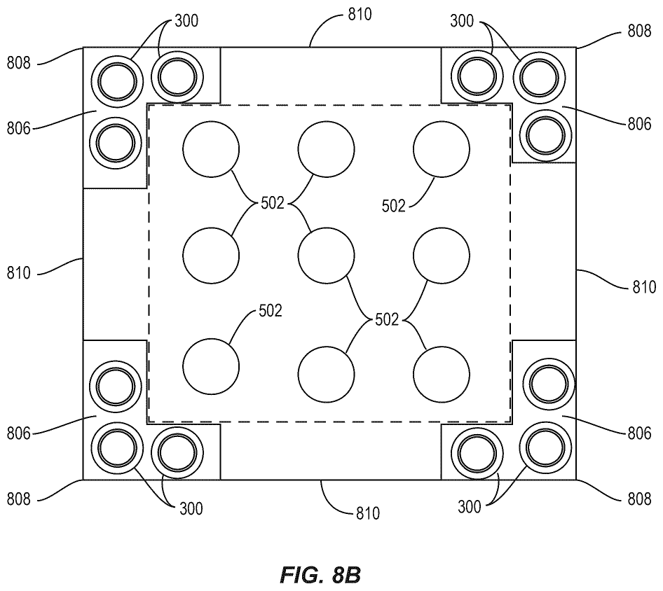

FIG. 8A illustrates another option similar to that illustrated in FIG. 7, but having a ring lead frame 800. Each corner 802 has balls 300 positioned there, and at least one ball on the sides 804. FIG. 8B is also similar but has a partial ring frame 806, and the balls 300 are positioned on these corner partial ring frames 806. Again, the balls 300 are positioned at the corners 808 and at least one ball on the sides 810.

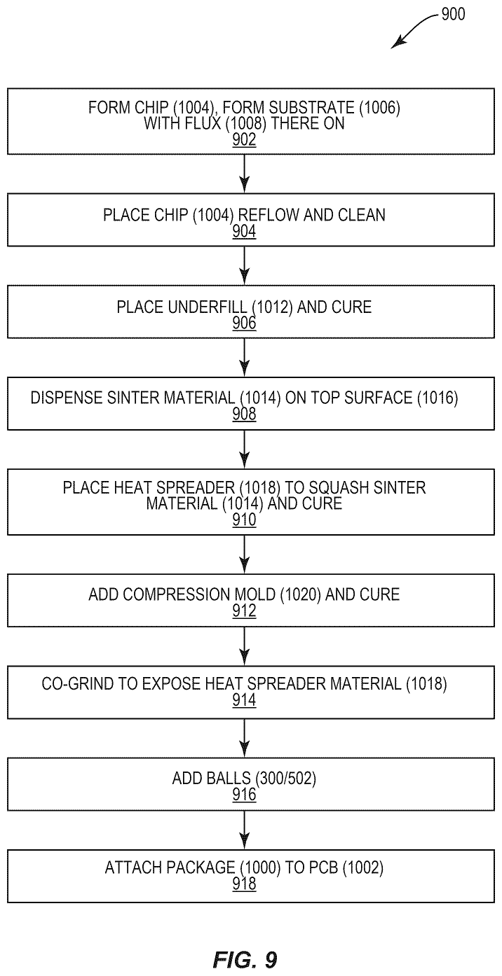

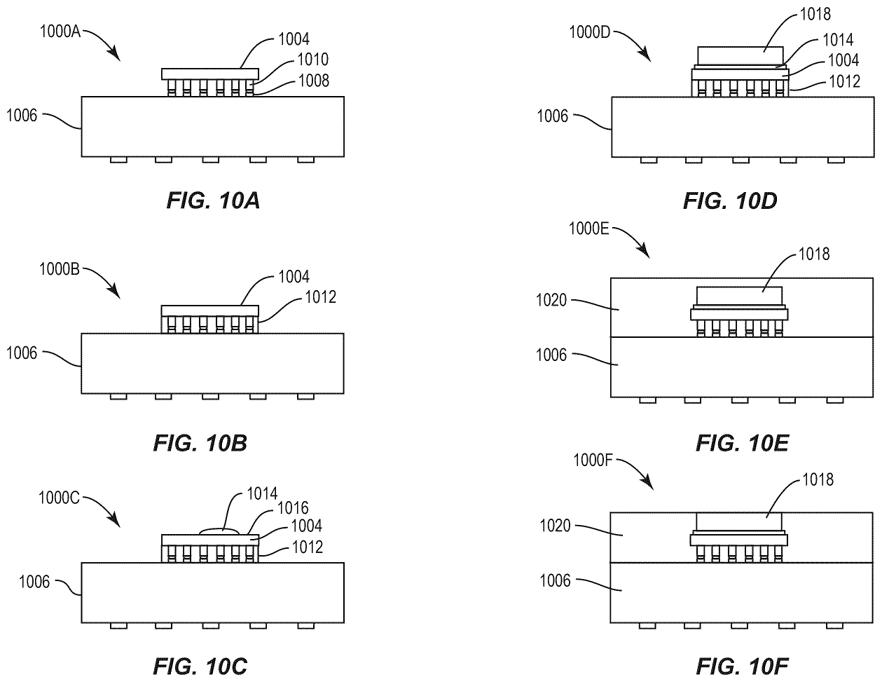

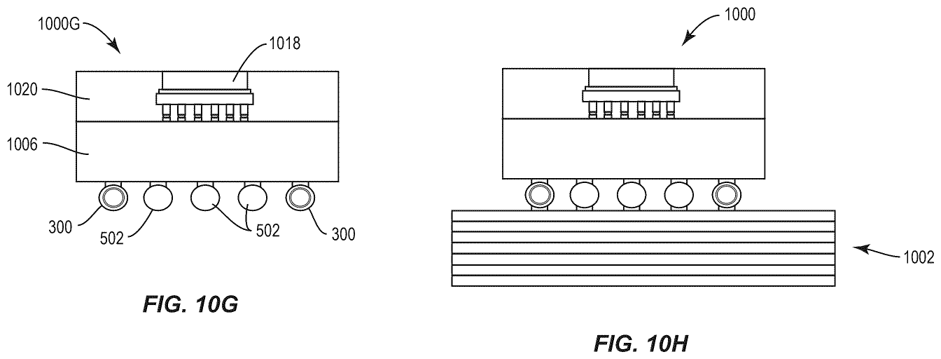

FIG. 9 illustrates a process 900 for forming a package 1000 that is attached to a PCB 1002 with reference to FIGS. 10A-10H to show the steps of the process 900. The process 900 begins by forming a die or chip 1004 and forming a substrate 1006 with flux 1008 printed thereon (block 902, see FIG. 10A) and intermediate product 1000A. The chip 1004 is placed on the substrate with pins or solder balls 1010 on the flux 1008; the assembly is reflowed and cleaned (block 904, FIG. 10A). Underfill 1012 is provided under the chip 1004 and cured (block 906, FIG. 10B) to provide intermediate product 1000B.

A sinter material 1014 is dispensed on a top surface 1016 of the chip 1004 (block 908, FIG. 10C) to form intermediate product 1000C. The heat spreader 1018 is placed on the sinter material 1014 (squashing same) and cured (block 910, FIG. 10D) to form intermediate product 1000D. The compression mold 1020 is added and cured (block 912, FIG. 10E) to form intermediate product 1000E. The intermediate product 1000E is co-ground to expose the heat spreader 1018 (block 914, FIG. 10F) to form intermediate product 1000F.

Balls 300 and 502 are then added to the intermediate product 1000F (block 916, FIG. 10G) to form intermediate product 1000G. This addition may be done through a flux print, solder ball 502, and ball 300 placement on the flux with a reflow step. The package 1000 is then attached to the PCB 1002 (block 918, FIG. 10H).

The BGA structures with drop-shock performance, according to aspects disclosed herein, may be provided in or integrated into any processor-based device having chips attached to substrates. While mobile devices that are subject to drops are specifically contemplated, the disclosure is not so limited. Accordingly, examples of processor-based devices, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

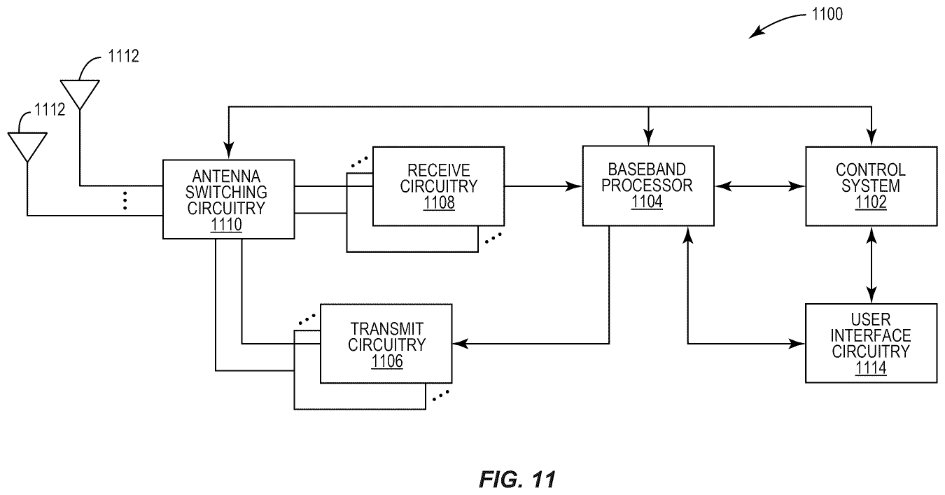

FIG. 11 is a schematic diagram of an exemplary communication device 1100 wherein the chips with the BGA structures disclosed herein can be provided. Herein, the communication device 1100 can be any type of communication device, such as those listed above, as well as access points, base stations (e.g., eNB or gNB), and any other type of wireless communication devices that support wireless communications, such as cellular, wireless local area network (WLAN), Bluetooth, Ultra-wideband (UWB), and near field communications.

More particularly, the communication device 1100 will generally include a control system 1102, a baseband processor 1104, transmit circuitry 1106, receive circuitry 1108, antenna switching circuitry 1110, multiple antennas 1112, and user interface circuitry 1114. In a non-limiting example, the control system 1102 can be a field-programmable gate array (FPGA) or an application-specific integrated circuit (ASIC) as an example and may include the BGA structures of the present disclosure. In this regard, the control system 1102 can include at least a microprocessor(s), an embedded memory circuit(s), and a communication bus interface(s). The receive circuitry 1108 receives radio frequency signals via the antennas 1112 and through the antenna switching circuitry 1110 from one or more base stations. A low noise amplifier and a filter of the receive circuitry 1108 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1104 processes the digitized received signal to extract the information or data bits conveyed in the received signal. This processing typically comprises demodulation, decoding, and error correction operations. The baseband processor 1104 is generally implemented in one or more digital signal processors (DSPs) and ASICs.

For transmission, the baseband processor 1104 receives digitized data, which may represent voice, data, or control information, from the control system 1102, which it encodes for transmission. The encoded data is output to the transmit circuitry 1106, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 1112 through the antenna switching circuitry 1110 to the antennas 1112. The multiple antennas 1112 and the replicated transmit and receive circuitries 1106, 1108 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A package comprising:
a substrate;
a chip positioned on the substrate;
a first plurality of uniform balls forming a ball grid array (BGA) and configured to provide electrical connections to the chip;
a second plurality of non-uniform balls positioned proximate an outer periphery of the substrate.

2. The package of claim 1, wherein each of the second plurality of non-uniform balls comprises a copper core.

3. The package of claim 2, wherein each of the second plurality of non-uniform balls comprises an outer solder plating layer.

4. The package of claim 3, wherein the outer solder plating layer is indium.

5. The package of claim 3, further comprising an intervening nickel layer positioned between the copper core and the outer solder plating layer.

6. The package of claim 1, wherein the second plurality of non-uniform balls are positioned around an entirety of the outer periphery of the substrate.

7. The package of claim 1, further comprising a heat spreader positioned on top of the chip.

8. The package of claim 1, further comprising a ring frame positioned on a bottom surface of the substrate.

9. The package of claim 8, wherein the second plurality of non-uniform balls are positioned on the ring frame.

10. The package of claim 1, wherein the second plurality of non-uniform balls are positioned only proximate corners of the substrate.

11. An assembly comprising:
a printed circuit board (PCB); and
a package bonded to the PCB through a ball grid array (BGA), the package comprising:
a substrate;
a chip positioned on the substrate;
the BGA positioned on a bottom surface of the substrate, the BGA comprising:
a first plurality of uniform balls configured to provide electrical connections to the chip and bond the package to the PCB;
a second plurality of non-uniform balls positioned proximate an outer periphery of the substrate.

12. The assembly of claim 11, wherein each of the second plurality of non-uniform balls comprises a copper core.

13. The assembly of claim 12, wherein each of the second plurality of non-uniform balls comprises an outer solder plating layer.

14. The assembly of claim 13, wherein the outer solder plating layer is indium.

15. The assembly of claim 13, further comprising an intervening nickel layer positioned between the copper core and the outer solder plating layer.

16. The assembly of claim 11, wherein the second plurality of non-uniform balls are positioned around an entirety of the outer periphery of the substrate.

17. The assembly of claim 11, further comprising a heat spreader positioned on top of the chip.

18. The assembly of claim 11 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

19. A method of attaching a package to a printed circuit board (PCB), comprising:
providing a first plurality of uniform balls in a ball grid array (BGA) of the package;
providing a second plurality of non-uniform balls in the BGA at an outer edge of the package; and
reflowing the uniform and non-uniform balls to attach the package to the PCB.

20. The method of claim 19, wherein providing the second plurality of non-uniform balls comprises providing non-uniform balls with a copper core and an indium outer solder plating layer.
